(19) United States
(12) Patent Application Publication
(10) Pub. No.: US 2026/0246455 A1
(43) Pub. Date: Aug. 20, 2026

(54) CIRCUITRY FOR PHASE ALIGNMENT OF MULTIPLE FREQUENCY DIVIDERS

(71) Applicant: Realtek Semiconductor Corp., HsinChu (TW)

(72) Inventors: Chi-Ling Hung, HsinChu (TW); Kuo-Wei Wu, HsinChu (TW)

(73) Assignee: Realtek Semiconductor Corp., HsinChu (TW)

(21) Appl. No.: 19/534,773

(22) Filed: Feb. 10, 2026

Related U.S. Application Data
(60) Provisional application No. 63/759,225, filed on Feb. 16, 2025.

(30) Foreign Application Priority Data
Jan. 12, 2026 (TW) 115101070

(51) Int. Cl. H03K 5/05; H03K 5/15

(52) U.S. Cl. CPC H03K 5/05; H03K 5/15006

(57) ABSTRACT

The present invention provides a circuitry including a clock buffer, a first circuit module, and a second circuit module. The clock buffer is configured to generate a first clock signal and a second clock signal. The first circuit module includes a first frequency divider configured to divide the first clock signal to generate a plurality of first divided clock signals. The second circuit module includes a second frequency divider configured to divide the first clock signal to generate a plurality of second divided clock signals. During the frequency division operation, both the first circuit module and the second circuit module utilize the second clock signal for phase alignment, thereby ensuring that the plurality of first divided clock signals and the plurality of second divided clock signals are phase-aligned.

### CROSS REFERENCE TO RELATED APPLICATIONS

This application claims the benefit of U.S. Provisional Application No. 63/759,225, filed on February 16th, 2025. The content of the application is incorporated herein by reference.

### BACKGROUND OF THE INVENTION

### 1. Field of the Invention

The present invention relates to frequency dividers, and more particularly, to a phase alignment method for a plurality of frequency dividers.

### 2. Description of the Prior Art

In a chip having multiple analog-to-digital converters (ADCs) and multiple digital-to-analog converters (DACs), since the multiple ADCs and the multiple DACs may require multiple clock signals with different frequencies, these ADCs or DACs are usually equipped with frequency dividers. These frequency dividers perform a frequency division operation on a high-frequency clock signal from a phase-locked loop (PLL) to generate multiple clock signals with required frequencies for internal operations. For example, referring to FIG. 1, frequency dividers 110 and 120 may be located in a first ADC and a second ADC, respectively. The frequency divider 110 performs a frequency division operation (divisor “2”) on a clock signal CK to generate a divided clock signal CK1, and the frequency divider 120 performs a frequency division operation (divisor “2”) on the clock signal CK to generate a divided clock signal CK2.

However, the architecture shown in FIG. 1 may cause a problem where the phases of the divided clock signals CK1 and CK2 used by the first ADC and the second ADC are not aligned. Specifically, referring to FIG. 2, assume that the frequency divider 110 has been enabled by an enable signal EN1 and generates the divided clock signal CK1. At this time, if the frequency divider 120 starts to be enabled by an enable signal EN2 and the first rising edge of the clock signal CK seen by it is at the position marked “x” in FIG. 2, the phase of the divided clock signal CK2 generated by the frequency divider 120 will have a 180-degree phase difference from the divided clock signal CK1 generated by the frequency divider 110, meaning the phases are not aligned. Conversely, if the first rising edge of the clock signal CK seen by the frequency divider 120 when it starts to be enabled by the enable signal EN2 is at the position marked “o” in FIG. 2, the phase of the divided clock signal CK2 generated by the frequency divider 120 will align with the divided clock signal CK1 generated by the frequency divider 110. As mentioned above, when the frequency dividers 110 and 120 are frequency dividers with a divisor of “2”, the generated divided clock signals CK1 and CK2 will have two phase possibilities.

Similarly, if the frequency dividers 110 and 120 are frequency dividers with divisors of “4”, “8”, “16”, etc., the generated divided clock signals CK1 and CK2 will respectively have “4”, “8”, “16”… kinds of phase possibilities, making phase alignment even more difficult.

In order to align the phases of the clock signals used by each of the above ADCs and DACs, another method is to transmit the clock signals of the required frequencies to each ADC and DAC simultaneously through a clock buffer. However, this method causes the clock buffer to have high power consumption, leads to mutual interference of multiple clock signals with different frequencies during transmission, requires many traces for the clock buffer to transmit many clock signals with different frequencies to multiple ADCs and multiple DACs, and requires stronger power traces and decoupling capacitors for the clock buffer to avoid the influence of clock signals with different frequencies on the power traces. Therefore, since this method results in higher power consumption and a larger chip area, it is not suitable for implementation.

### SUMMARY OF THE INVENTION

Therefore, one of the objectives of the present invention is to provide a phase alignment method for a plurality of frequency dividers to solve the problems mentioned in the prior art.

In one embodiment of the present invention, a circuitry is disclosed. The circuitry comprises a clock buffer, a first circuit module, and a second circuit module. The clock buffer is configured to generate a first clock signal and a second clock signal. The first circuit module comprises a first frequency divider, wherein the first frequency divider is configured to receive the first clock signal and the second clock signal, and perform a frequency division operation on the first clock signal to generate a plurality of first divided clock signals. The second circuit module comprises a second frequency divider, wherein the second frequency divider is configured to receive the first clock signal and the second clock signal, and perform the frequency division operation on the first clock signal to generate a plurality of second divided clock signals. During the frequency division operation, the first circuit module and the second circuit module utilize the second clock signal to perform a phase alignment operation, so that the plurality of first divided clock signals and the plurality of second divided clock signals are phase-aligned.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of two frequency dividers respectively performing frequency division on a clock signal in the prior art.

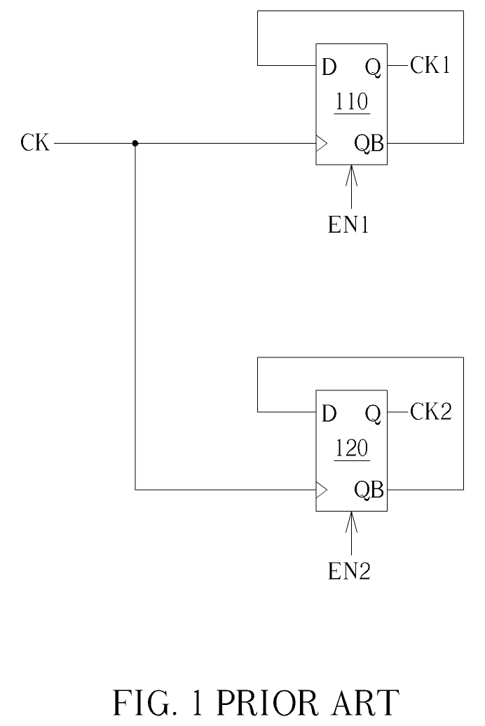

FIG. 2 is a schematic diagram showing that two divided clock signals generated by the two frequency dividers shown in FIG. 1 may have phase misalignment.

FIG. 3 is a schematic diagram of a circuitry according to an embodiment of the present invention.

FIG. 4 is a schematic diagram of a part of a clock buffer and a receiving circuit according to an embodiment of the present invention.

FIG. 5 is a schematic diagram of a buffer according to an embodiment of the present invention.

FIG. 6 is a timing diagram of an enable signal and a delayed enable signal.

FIG. 7 is a timing diagram of certain signals shown in FIG. 4 according to an embodiment of the present invention.

FIG. 8 is a schematic diagram showing that divided clock signals generated by different ADCs shown in FIG. 3 can be phase-aligned according to an embodiment of the present invention.

### DETAILED DESCRIPTION

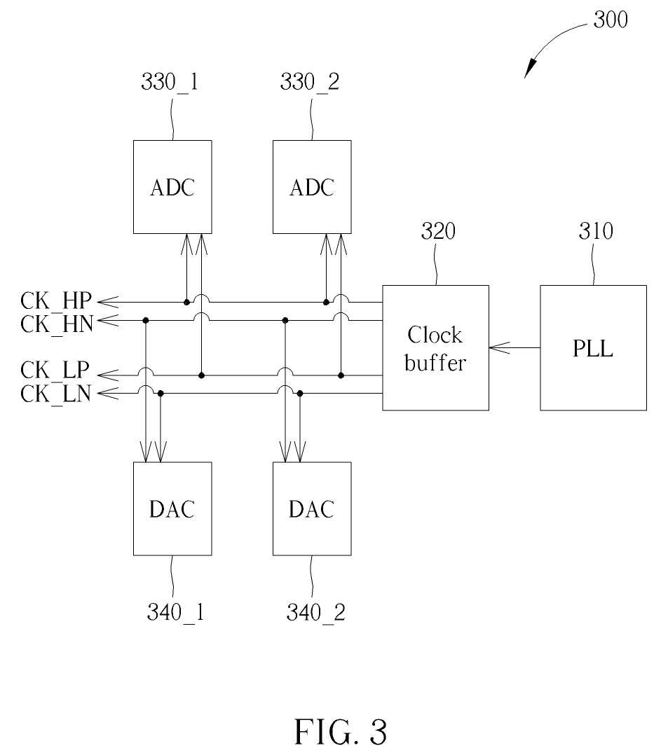

FIG. 3 is a schematic diagram of a circuitry 300 according to an embodiment of the present invention. As shown in FIG. 3, the circuitry 300 comprises a phase-locked loop (PLL) 310, a clock buffer 320, and a plurality of circuit modules. In this example, the plurality of circuit modules are illustrated as a plurality of ADCs 330_1, 330_2 and a plurality of DACs 340_1, 340_2. In this embodiment, the ADCs 330_1, 330_2 and the DACs 340_1, 340_2 need to use multiple clock signals with different frequencies, and each of the ADCs 330_1, 330_2 and the DACs 340_1, 340_2 has a frequency divider to divide the clock signal from the PLL 310 to generate multiple divided clock signals for internal operations.

In the operation of the circuitry 300, the PLL 310 generates four clock signals CK_HP, CK_HN, CK_LP, and CK_LN. The clock signals CK_HP and CK_HN are differential signals with a high frequency, meaning the clock signals CK_HP and CK_HN have the same frequency but opposite phases. The clock signals CK_LP and CK_LN are differential signals with a low frequency (i.e., the frequency of the clock signals CK_LP and CK_LN is lower than the frequency of the clock signals CK_HP and CK_HN), meaning the clock signals CK_LP and CK_LN have the same frequency but opposite phases. In this embodiment, the ADCs 330_1 and 330_2 are used to receive the clock signals CK_HP and CK_LP, and the DACs 340_1 and 340_2 are used to receive the clock signals CK_HN and CK_LN, but the present invention is not limited thereto. After receiving the clock signals, the ADCs 330_1, 330_2 and the DACs 340_1, 340_2 perform a frequency division operation on the clock signal CK_HP/CK_HN to generate multiple divided clock signals for internal use. During the frequency division operation, the ADCs 330_1, 330_2 and the DACs 340_1, 340_2 utilize the clock signal CK_LP/CK_LN to perform a phase alignment operation, so that the multiple divided clock signals generated by each of the ADCs 330_1, 330_2 and the DACs 340_1, 340_2 are aligned with each other in phase.

In this embodiment, in order to allow the ADCs 330_1, 330_2 and the DACs 340_1, 340_2 to use the clock signal CK_LP/CK_LN for the phase alignment operation during the frequency division operation, the frequency of the clock signals CK_LP and CK_LN corresponds to the greatest common divisor of multiple frequencies of the multiple divided clock signals generated by the ADCs 330_1, 330_2 and the DACs 340_1, 340_2 performing the frequency division operation on the clock signal CK_HP/CK_HN. For example, assume that the frequency of the clock signals CK_HP and CK_HN is “F”, and the frequencies of the divided clock signals required by the ADCs 330_1, 330_2 and the DACs 340_1, 340_2 are “F/2”, “F/4”, “F/8”, and “F/16”. Then, the frequency of the clock signals CK_LP and CK_LN is “F/16”. In another example, assume that the frequencies of the divided clock signals required by the ADCs 330_1, 330_2 and the DACs 340_1, 340_2 are “F/2”, “F/3”, and “F/4”. Then, the frequency of the clock signals CK_LP and CK_LN is “F/12”.

Through the architecture of the circuitry 300, regardless of how many frequencies are required by the ADCs 330_1,330_2 and the DACs 340_1, 340_2, the PLL 310 only needs to generate four clock signals CK_HP, CK_HN, CK_LP, and CK_LN, and each of the ADCs 330_1, 330_2 and the DACs 340_1, 340_2 only needs to receive two clock signals. Therefore, the PLL 310 and the clock buffer 320 have lower power consumption, and the connections from the clock buffer 320 to the ADCs 330_1, 330_2 and the DACs 340_1, 340_2 have a small number of traces, thereby improving signal quality and reducing chip area.

It should be noted that the clock signals generated by the PLL 310 shown in FIG. 3 are differential signals to avoid electromagnetic interference. However, in other embodiments, the PLL 310 may not need to transmit differential signals; that is, the PLL 310 can transmit only two clock signals CK_HP and CK_LP to the ADCs 330_1, 330_2 and the DACs 340_1, 340_2.

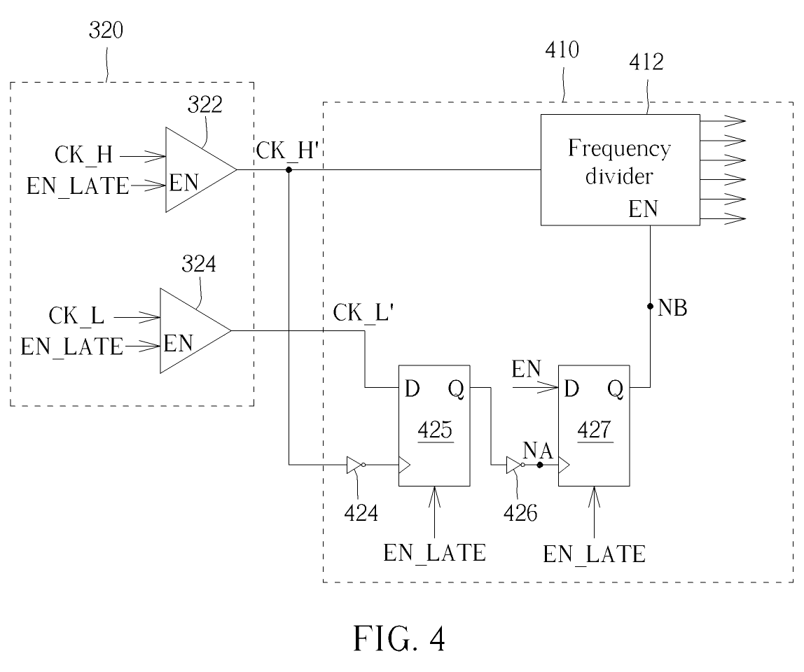

FIG. 4 is a schematic diagram of a part of the clock buffer 320 and a receiving circuit 410 according to an embodiment of the present invention, wherein the receiving circuit 410 can be disposed in any one of the ADCs 330_1, 330_2 and the DACs 340_1, 340_2. As shown in FIG. 4, the clock buffer 320 includes two buffers 322 and 324, and the receiving circuit 410 includes a frequency divider 412, two inverters 424 and 426, and two sampling circuits (implemented by D-type flip-flops 425 and 427).

In one embodiment, each of the ADCs 330_1, 330_2 and the DACs 340_1, 340_2 includes the receiving circuit 410, and the clock buffer 320 is provided with corresponding two buffers 322 and 324 for each of the ADCs 330_1, 330_2 and the DACs 340_1, 340_2.

In the operation of the clock buffer 320 and the receiving circuit 410 shown in FIG. 4, the buffer 322 receives a clock signal CK_H and selectively generates a buffered clock signal CK_H’ through the control of a delayed enable signal EN_LATE. The clock signal CK_H can be any one of the clock signals CK_HP and CK_HN shown in FIG. 3, meaning the clock signal CK_H is a high-frequency clock signal. In addition, when the delayed enable signal EN_LATE enables the buffer 322, the buffer 322 generates the buffered clock signal CK_H’ according to the clock signal CK_H; and when the delayed enable signal EN_LATE does not enable the buffer 322, the buffer 322 does not output the buffered clock signal CK_H’ (e.g., outputs a logic value “1” corresponding to a high voltage). The buffer 324 receives a clock signal CK_L and selectively generates a buffered clock signal CK_L’ through the control of the delayed enable signal EN_LATE. The clock signal CK_L can be any one of the clock signals CK_LP and CK_LN shown in FIG. 3, meaning the clock signal CK_L is a low-frequency clock signal. In addition, when the delayed enable signal EN_LATE enables the buffer 324, the buffer 324 generates the buffered clock signal CK_L’ according to the clock signal CK_L; and when the delayed enable signal EN_LATE does not enable the buffer 324, the buffer 324 does not output the buffered clock signal CK_L’ (e.g., outputs a logic value “1” corresponding to a high voltage).

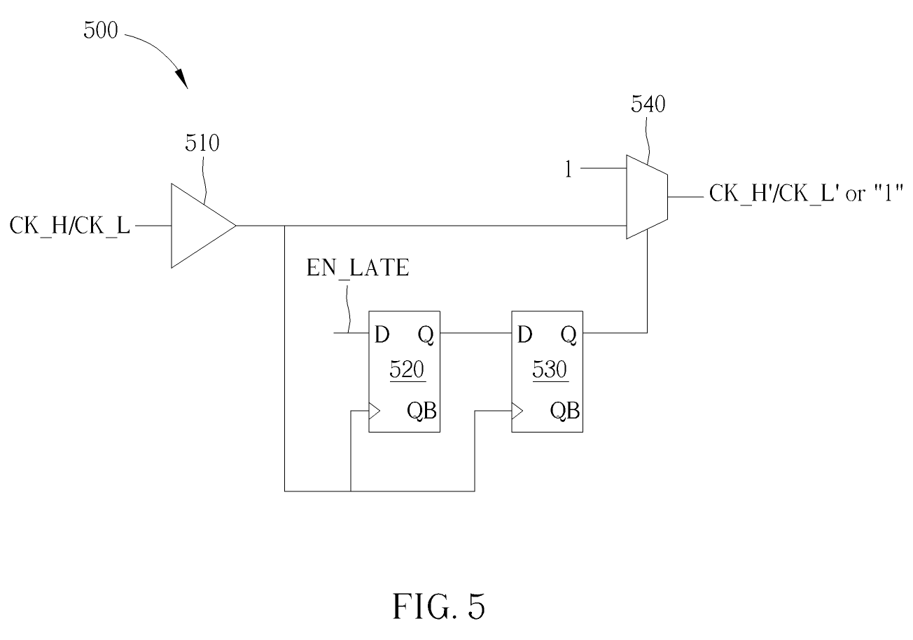

FIG. 5 is a schematic diagram of a buffer 500 according to an embodiment of the present invention, wherein the buffer 500 can be used to implement any one of the buffers 322 and 324 shown in FIG. 4. As shown in FIG. 5, the buffer 500 includes a buffer circuit 510, two sampling circuits (implemented by D-type flip-flops 520 and 530), and a multiplexer 540. In the operation of the buffer 500, the clock signal CK_H/CK_L is transmitted to the D-type flip-flops 520, 530 and the multiplexer 540 through the buffer circuit 510. The D-type flip-flops 520 and 530 sequentially use the clock signal CK_H/CK_L to sample the delayed enable signal EN_LATE to control the multiplexer 540 to select the clock signal CK_H/CK_L or a logic value “1” as the output. Specifically, when the output of the D-type flip-flop 530 has a high voltage level, the multiplexer 540 outputs the clock signal CK_H/CK_L as the buffered clock signal CK_H’/CK_L’; and when the output of the D-type flip-flop 530 has a low voltage level, the multiplexer 540 outputs the logic value “1”.

It should be noted that the circuit architecture of the buffer 500 shown in FIG. 5 is only an example and not a limitation of the present invention. In other embodiments, as long as the buffer 500 can selectively generate the buffered clock signal CK_H’/CK_L’ according to the clock signal CK_H/CK_L based on the delayed enable signal EN_LATE, it can have different circuit designs.

In the operation of the receiving circuit 410, the D-type flip-flop 425 is controlled by the delayed enable signal EN_LATE to determine whether to operate normally. For example, when the delayed enable signal EN_LATE enables the D-type flip-flop 425, the D-type flip-flop 425 performs normal operation, meaning the D-type flip-flop 425 samples the buffered clock signal CK_L’ according to the buffered clock signal CK_H’ to generate a first sampled signal. When the delayed enable signal EN_LATE does not enable the D-type flip-flop 425, the D-type flip-flop 425 is reset so that its output corresponds to a logic value “0”. Specifically, the inverter 424 performs an inversion operation on the buffered clock signal CK_H’ to generate an inverted clock signal. When the D-type flip-flop 425 operates normally, the D-type flip-flop 425 uses the inverted clock signal to sample the buffered clock signal CK_L’ to generate the first sampled signal.

Next, the D-type flip-flop 427 is controlled by the delayed enable signal EN_LATE to determine whether to operate normally. For example, when the delayed enable signal EN_LATE enables the D-type flip-flop 427, the D-type flip-flop 427 performs normal operation, meaning the D-type flip-flop 427 samples an enable signal EN according to the first sampled signal outputted by the D-type flip-flop 425 to generate a sampled enable signal to the frequency divider 412. When the delayed enable signal EN_LATE does not enable the D-type flip-flop 427, the D-type flip-flop 427 is reset so that its output corresponds to a logic value “0”. Specifically, the inverter 426 performs an inversion operation on the first sampled signal outputted by the D-type flip-flop 425 to generate an inverted first sampled signal. When the D-type flip-flop 427 operates normally, the D-type flip-flop 427 uses the inverted first sampled signal to sample the enable signal EN to generate the sampled enable signal.

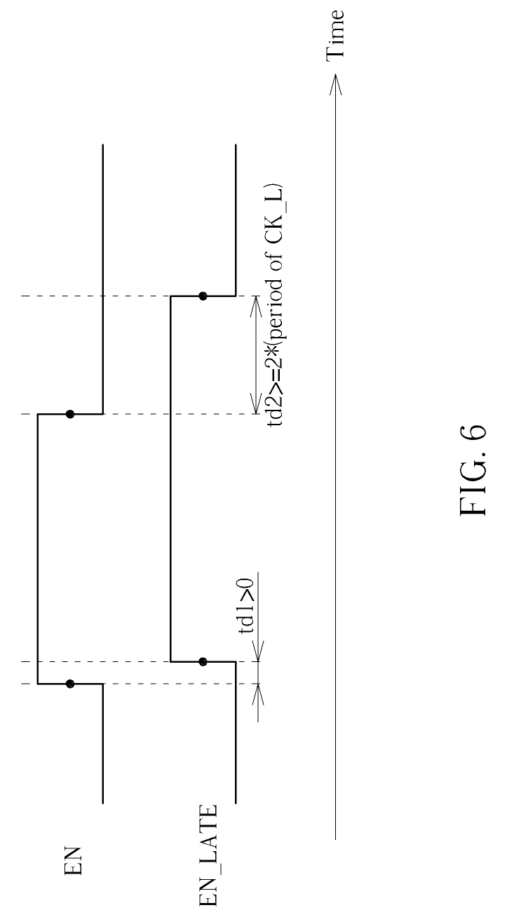

Referring to FIG. 6, which is a timing relationship diagram of the enable signal EN and the delayed enable signal EN_LATE of FIG. 4. As shown in FIG. 6, assuming that the high voltage level (logic value “1”) of the enable signal EN and the delayed enable signal EN_LATE represents an enabled state, and the low voltage level (logic value “0”) represents a disabled state, then the start enable time (rising edge time) of the delayed enable signal EN_LATE is later than the start enable time (rising edge time) of the enable signal EN. That is, the rising edge time difference td1 between the delayed enable signal EN_LATE and the enable signal EN shown in the figure is greater than zero. In addition, the start disable time (falling edge time) of the delayed enable signal EN_LATE is later than the start disable time (falling edge time) of the enable signal EN, and the start disable time difference (falling edge time difference) td2 between the delayed enable signal EN_LATE and the enable signal EN is greater than or equal to twice the period of the clock signal CK_L.

It should be noted that the enable signal EN and the delayed enable signal EN_LATE shown in FIG. 4 and FIG. 6 can be generated internally by the ADCs 330_1, 330_2 and the DACs 340_1, 340_2 themselves, or generated by the clock buffer 320 and then transmitted to the ADCs 330_1, 330_2 and the DACs 340_1, 340_2.

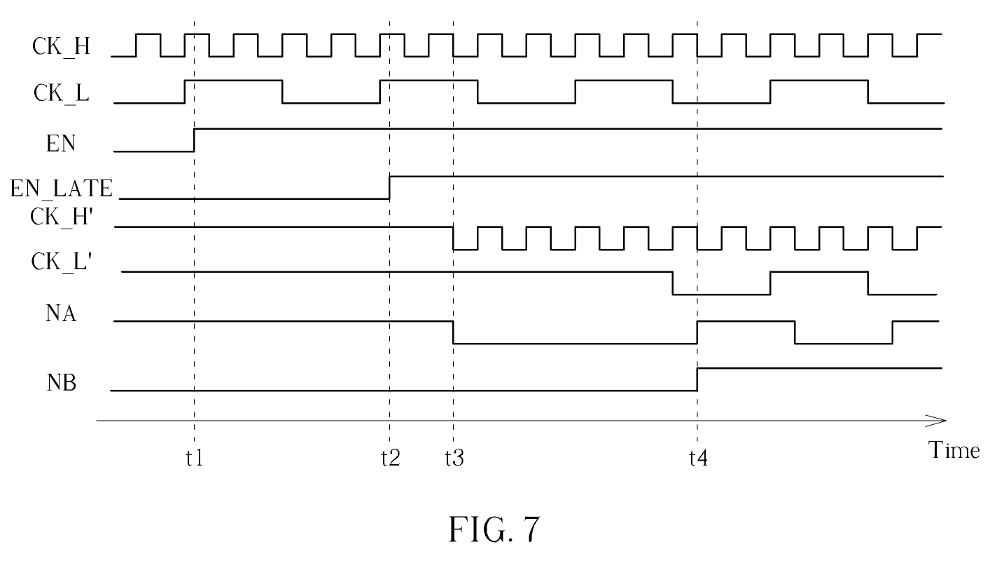

FIG. 7 is a timing diagram of certain signals shown in FIG. 4 according to an embodiment of the present invention. The signal at the node NA shown in FIG. 7 is the inverted first sampled signal generated by the inverter 426, and the signal at the node NB is the sampled enable signal generated by the D-type flip-flop 427. Referring to FIG. 4 and FIG. 7 simultaneously, at time t1, the enable signal EN transitions from the low voltage level to the high voltage level, i.e., the enable signal EN switches from logic value “0” to logic value “1” to enter the enabled state. At time t2, the delayed enable signal EN_LATE transitions from the low voltage level to the high voltage level, i.e., the delayed enable signal EN_LATE switches from logic value “0” to logic value “1” to enter the enabled state. At time t3, the falling edge of the buffered clock signal CK_H’ starts to appear first, while the buffered clock signal CK_L’ still has a high voltage level (logic value “1”), causing the inverted first sampled signal at the node NA to start showing a falling edge. At time t4, after the buffered clock signal CK_L’ becomes a low voltage level (logic value “0”), when the first falling edge of the buffered clock signal CK_H’ appears, both the inverted first sampled signal at the node NA and the sampled enable signal at the node NB show a rising edge, thereby starting to enable the frequency divider 412.

After the frequency divider 412 is enabled, the frequency divider 412 can perform multiple frequency division operations on the buffered clock signal CK_H’ to generate multiple divided clock signals for use inside the circuit. It should be noted that since the circuit implementation of the frequency divider 412 is well known to those skilled in the art, details are not described in this specification.

On the other hand, if the frequency divider 412 needs to be disabled, referring to FIG. 4 and FIG. 6, the following steps are sequentially performed: (1) The enable signal EN first transitions from the high voltage level to the low voltage level, i.e., the enable signal EN switches from logic value “1” to logic value “0” to enter the disabled state. (2) Through the sampling at the rising edge of the inverted first sampled signal at the node NA, the sampled enable signal at the node NB transitions from the high voltage level to the low voltage level to enter the disabled state, and the disabling of the frequency divider 412 is completed. (3) The delayed enable signal EN_LATE transitions from the high voltage level to the low voltage level, i.e., the delayed enable signal EN_LATE switches from logic value “1” to logic value “0” to enter the disabled state.

Summarizing the above, regardless of whether the frequency divider 412 is to be enabled or disabled, the corresponding time point is the time point when the rising edge of the inverted first sampled signal at the node NA in FIG. 7 appears.

In the embodiment of FIG. 4, since the D-type flip-flop 425 samples the low-frequency buffered clock signal CK_L’ according to the high-frequency buffered clock signal CK_H’, the frequency of the inverted first sampled signal at the node NA is equal to the frequency of the buffered clock signal CK_L’. In addition, since the rising edge of the inverted first sampled signal at the node NA aligns with the falling edge of the buffered clock signal CK_H’, the voltage level switching of the sampled enable signal at the node NB must be near the falling edge of the buffered clock signal CK_H’. In this way, when the frequency divider 412 needs to be enabled, the maximum timing margin can be obtained. In addition, since the time difference when the frequency divider 412 is enabled or disabled is necessarily an integer multiple of the period of the buffered clock signal CK_L’, when the frequency divider 412 needs to be disabled, it must start when both the divided clock signal and the buffered clock signal CK_L’ are at logic value “0”. Therefore, glitch phenomena can be avoided.

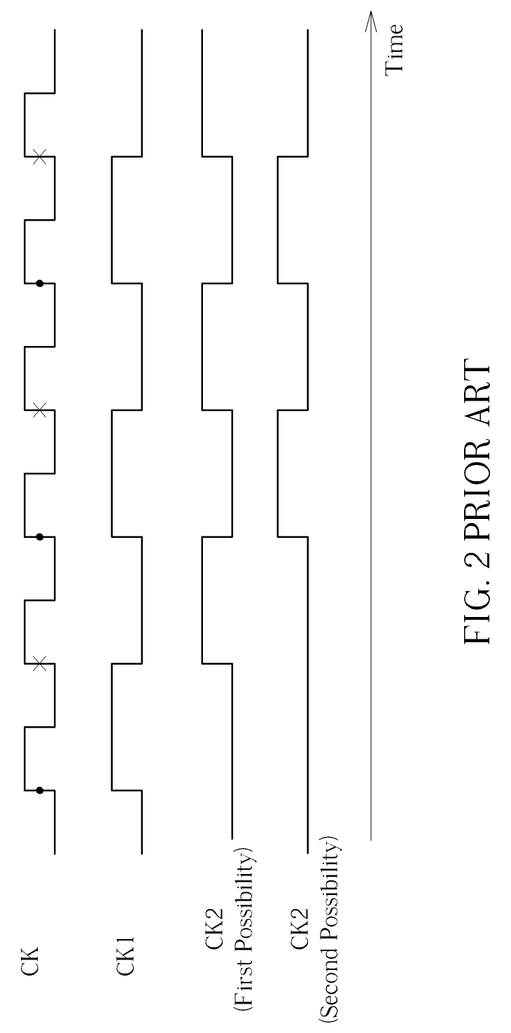

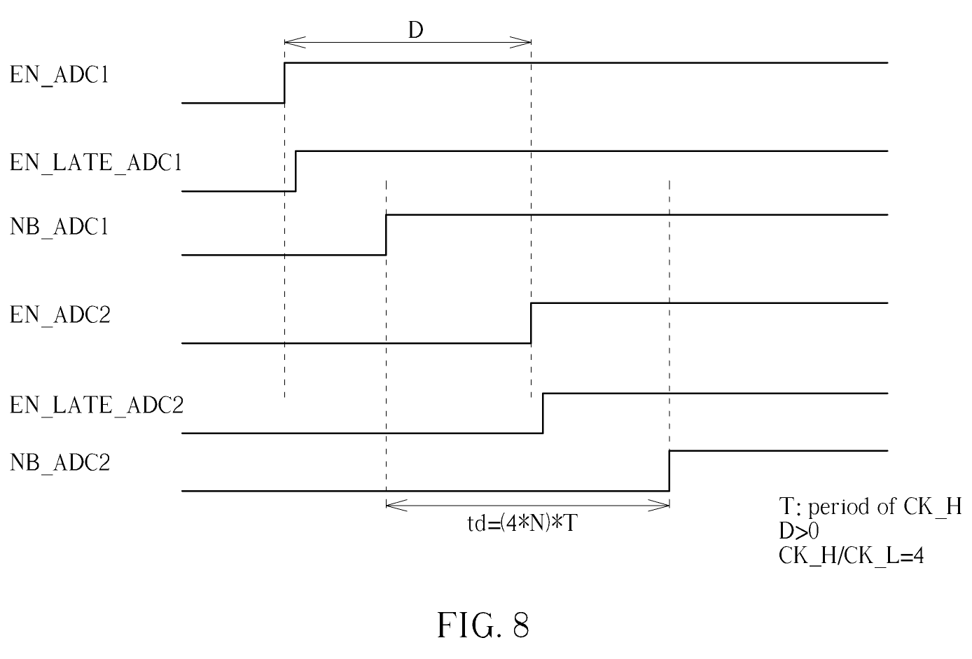

Through the design of the embodiments in FIG. 3 and FIG. 4, the divided clock signals generated by each of the ADCs 330_1, 330_2 and the DACs 340_1, 340_2 can be phase-aligned, avoiding the problem of possible phase misalignment of the divided clock signals generated by each ADC and DAC in the prior art shown in FIG. 2. Specifically, referring to the timing diagram shown in FIG. 8, EN_ADC1 represents the enable signal EN of FIG. 4 used for the ADC 330_1, EN_LATE_ADC1 represents the delayed enable signal EN_LATE of FIG. 4 used for the ADC 330_1, NB_ADC1 represents the sampled enable signal at the node NB of the receiving circuit 410 of FIG. 4 used for the ADC 330_1, EN_ADC2 represents the enable signal EN of FIG. 4 used for the ADC 330_2, EN_LATE_ADC2 represents the delayed enable signal EN_LATE of FIG. 4 used for the ADC 330_2, and NB_ADC2 represents the sampled enable signal at the node NB of the receiving circuit 410 of FIG. 4 used for the ADC 330_2. In addition, in this embodiment, it is assumed that the frequency of the clock signal CK_H is four times the frequency of the clock signal CK_L. “T” in FIG. 8 represents the period of the clock signal CK_H, “D” represents the enable time difference (i.e., rising edge time difference) between the enable signal EN_ADC1 for the ADC 330_1 and the enable signal EN_ADC2 for the ADC 330_2, and “N” is any suitable positive integer. Referring to FIG. 8, regardless of the value of the enable time difference D between the enable signal EN_ADC1 of the ADC 330_1 and the enable signal EN_ADC2 of the ADC 330_2, the time difference td between the sampled enable signal at the node NB_ADC1 of the ADC 330_1 and the sampled enable signal at the node NB_ADC2 of the ADC 330_2 must be a difference of (4*N)*T. This is because, ignoring trace transmission errors and circuit mismatch factors, the rising edges of the inverted first sampled signals at the node NA of different ADCs 330_1 and 330_2 in FIG. 4 will be completely aligned, and the frequency of the inverted first sampled signal at the node NA will be equal to the frequency of the clock signal CK_L.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A circuitry, comprising:
a clock buffer, configured to generate a first clock signal and a second clock signal;
a first circuit module, comprising a first frequency divider, wherein the first frequency divider is configured to receive the first clock signal and the second clock signal, and perform a frequency division operation on the first clock signal to generate a plurality of first divided clock signals; and
a second circuit module, comprising a second frequency divider, wherein the second frequency divider is configured to receive the first clock signal and the second clock signal, and perform the frequency division operation on the first clock signal to generate a plurality of second divided clock signals;
wherein the first circuit module and the second circuit module utilize the second clock signal to perform a phase alignment operation during the frequency division operation, so that the plurality of first divided clock signals and the plurality of second divided clock signals are phase-aligned.

2. The circuitry of claim 1, wherein the clock buffer comprises:
a first buffer, configured to receive the first clock signal and selectively generate a buffered first clock signal through control of a delayed enable signal; and
a second buffer, configured to receive the second clock signal and selectively generate a buffered second clock signal through control of the delayed enable signal; and
the first circuit module and/or the second circuit module comprises a receiving circuit, and the receiving circuit comprises:
a first sampling circuit, configured to sample the buffered second clock signal according to the buffered first clock signal to generate a first sampled signal; and
a second sampling circuit, configured to sample an enable signal according to the first sampled signal to generate a sampled enable signal to the first frequency divider;
wherein a start enable time of the delayed enable signal is later than a start enable time of the enable signal.

3. The circuitry of claim 2, wherein both the first circuit module and the second circuit module comprise the receiving circuit.

4. The circuitry of claim 2, wherein the receiving circuit further comprises:
a first inverter, configured to perform an inversion operation on the buffered first clock signal to generate an inverted clock signal; wherein the first sampling circuit samples the buffered second clock signal according to the inverted clock signal to generate the first sampled signal; and
a second inverter, configured to perform an inversion operation on the first sampled signal to generate an inverted first sampled signal; wherein the second sampling circuit is configured to sample the enable signal according to the inverted first sampled signal to generate the sampled enable signal to the first frequency divider.

5. The circuitry of claim 2, wherein the first sampling circuit and the second sampling circuit are controlled by the delayed enable signal; when the delayed enable signal enables the first sampling circuit and the second sampling circuit, the first sampling circuit samples the buffered second clock signal according to the buffered first clock signal to generate the first sampled signal, and the second sampling circuit samples the enable signal according to the first sampled signal to generate the sampled enable signal to the first frequency divider.

6. The circuitry of claim 2, wherein a start disable time of the delayed enable signal is later than a start disable time of the enable signal.

7. The circuitry of claim 6, wherein a frequency of the second clock signal is lower than a frequency of the first clock signal, and a difference between the start disable time of the delayed enable signal and the start disable time of the enable signal is greater than or equal to twice a period of the second clock signal.

8. The circuitry of claim 7, wherein the plurality of first divided clock signals have different frequencies, the plurality of second divided clock signals have different frequencies, and the frequency of the second clock signal is a greatest common divisor of multiple frequencies of the plurality of first divided clock signals or the plurality of second divided clock signals.

9. The circuitry of claim 1, wherein the plurality of first divided clock signals have different frequencies, the plurality of second divided clock signals have different frequencies, and a frequency of the second clock signal is a greatest common divisor of multiple frequencies of the plurality of first divided clock signals or the plurality of second divided clock signals; and the clock buffer does not transmit other clock signals to the first circuit module and the second circuit module.

10. The circuitry of claim 1, wherein the first circuit module and the second circuit module are analog-to-digital converters (ADCs) or digital-to-analog converters (DACs).
